(19) United States
(12) Patent Application Publication
(10) Pub. No.: US 2025/0359597 A1
(43) Pub. Date: Nov. 27, 2025

(54) An Aerosol Generating System Comprising an Electrolytic Capacitor and a Visual Indicator

(71) Applicant: JT International SA, Geneva (CH)

(72) Inventors: Alec Wright, Guildford (GB); Grzegorz Aleksander Pilatowicz, Grens (CH)

(73) Assignee: JT International SA, Geneva (CH)

(21) Appl. No.: 18/871,666

(22) PCT Filed: Jun. 22, 2023
(86) PCT No.: PCT/EP2023/066961

§ 371 Date: Dec. 4, 2024

(30) Foreign Application Priority Data
Jun. 24, 2022 (EP) 22181093.0

(51) Int. Cl. A24F 40/53; A24F 40/10; H02J 7/34

(52) U.S. Cl. CPC A24F 40/53; A24F 40/10; H02J 7/345

(57) ABSTRACT

An aerosol generating system includes an aerosol generating article and an aerosol generating device that is adapted to receive the article in use. The article includes a capacitor that contains an electrolyte which, when heated, generates an aerosol for inhalation by a user. The device also includes a visual indicator and a controller that is adapted to estimate or determine the amount of electrolyte in the capacitor and then control the visual indicator based on the amount of electrolyte.

### TECHNICAL FIELD

The present disclosure relates generally to an aerosol generating system that includes an aerosol generating article, and in particular an aerosol generating article which is adapted to be received in an aerosol generating device for generating an aerosol for inhalation by a user.

The present disclosure is particularly applicable to a portable (hand-held) aerosol generating device.

### TECHNICAL BACKGROUND

Devices which heat, rather than burn, an aerosol generating material to produce an aerosol for inhalation have become popular with consumers in recent years. A commonly available reduced-risk or modified-risk device is the heated material aerosol generating device, or so-called heat-not-burn device. Devices of this type generate an aerosol or vapour by heating an aerosol generating material to a temperature typically in the range 150° C. to 300° C. This temperature range is quite low compared to an ordinary cigarette. Heating the aerosol generating material to a temperature within this range, without burning or combusting the aerosol generating material, generates a vapour which typically cools and condenses to form an aerosol for inhalation by a user of the device.

Such devices may use one of a number of different approaches to provide heat to the aerosol generating material. All approaches for heating the aerosol generating material require some sort of power source such as a battery, which adds to the size and weight of the device. Embodiments of the present disclosure seek to provide a power source in the aerosol generating article which may be used to supplement or partially replace the power source in the device. This may result in a smaller and lighter device, which is beneficial for the user, while maintaining accurate control of the heating of the aerosol generating material and optimising the characteristics of the generated aerosol. The power source is a capacitor which includes an electrolyte which, when heated, generates an aerosol for inhalation by a user. Embodiments of the present disclosure provide a visual indication to the user of the amount of electrolyte in the capacitor.

### SUMMARY OF THE DISCLOSURE

According to a first aspect of the present disclosure, there is provided an aerosol generating system comprising:
an aerosol generating article (or consumable) comprising a capacitor, the capacitor comprising an electrolyte which, when heated, generates an aerosol for inhalation by a user; and
an aerosol generating device adapted to receive, in use, the aerosol generating article, the aerosol generating device comprising:
a visual indicator; and
a controller adapted to:
   estimate or determine the amount of electrolyte in the capacitor; and control the visual indicator based on the amount of electrolyte, i.e., so as to visually indicate to the user the amount of electrolyte remaining in the capacitor.

The electrolyte is aerosolisable, i.e., capable of being converted into an aerosol by heating, which aerosol is then inhaled by the user. Heating the capacitor therefore results in the electrolyte that is contained within the capacitor being converted into an aerosol and the aerosolised electrolyte is then inhaled by the user. Because the aerosolised electrolyte is inhaled by the user, the amount of electrolyte within the capacitor will decrease over the course of a vaping session.

The capacitor may have any suitable construction, but in a preferred embodiment it is a supercapacitor such as an electric double-layer supercapacitor. The capacitor may further comprise a pair of electrodes and a porous separator between the electrodes. The first electrode may be a positive electrode and the second electrode may be a negative electrode, or vice versa. The electrodes and the separator are immersed in the electrolyte.

Like a conventional capacitor, in an electric double-layer supercapacitor electrical charge is stored in the electrical field between the electrodes and the capacitance is a function of the surface area of the electrodes, the distance between them, and the dielectric constant of the separator material. The capacitor has a higher power density than a conventional power source such as a battery. When the capacitor is charged by an external circuit connected to the pair of electrodes, cations in the electrolyte migrate toward the negative electrode and the anions migrate to the positive electrode, while the electrons travel through the external circuit from the negative to the positive electrode. Two layers of charge with opposite polarity (an electric double-layer) are therefore formed at the interfaces with the electrodes. When charging finishes, positive electric charges on the positive electrode and anions in the electrolyte attract each other while negative electric charges on the negative electrode and cations in the electrolyte attract each other in order to stabilize the double layers on the electrodes. A stable voltage is generated. When the capacitor is discharged, the reverse processes happen.

Each electrode may comprise at least one carbon-based electrode layer, for example, a layer of porous charcoal material or activated carbon which has a high specific surface area per volume and compatibility with the proposed electrolyte.

Each electrode may further comprise a current collector, which may comprise a metal foil layer, for example, an aluminium foil layer. A carbon-based electrode layer may be positioned adjacent one or both sides of a current collector. Each carbon-based electrode layer may be formed as a coating. Such electrodes may be manufactured relatively easily and cheaply using materials that are already known to be used in aerosol generating articles.

As will be understood by one of ordinary skill in the art, the electrolyte fulfils two functions. Firstly it permits the cation and anion migration that occurs when the capacitor is charged or discharged, and secondly, when heated, it forms an aerosol that is safe to be inhaled by the user and has good characteristics. The electrolyte should therefore be selected accordingly. The electrolyte is preferably a food-grade electrolyte and may comprise one or more of sodium chloride, sodium citrate, sodium bicarbonate, potassium chloride, calcium lactate, calcium carbonate, tricalcium phosphate, magnesium citrate, magnesium carbonate, citric acid, tartaric acid, benzoic acid, glycerol and any suitable equivalents, for example. The electrolyte may optionally include a gelling agent such as polyvinyl alcohol, gellan gum or xanthan gum, for example. In one example, the electrolyte may comprise sodium chloride and glycerol, and optionally polyvinyl alcohol as a gelling agent. Such an electrolyte has been found to permit cation and anion migration and is also safe for inhalation by the user.

When all of the electrolyte has been vapourised, the capacitor may not be further discharged or charged, and the aerosol generating article may need to be disposed of appropriately or re-filled with electrolyte.

The separator must provide dielectric separation between the pair of oppositely charged electrodes. The separator also stores electrolyte in its pores and permits the passage of cations and anions during the charging and discharging processes. The separator may comprise any suitable material. The separator may comprise a plant derived material and in particular may comprise a tobacco material, for example, a porous tobacco sheet, or it may comprise any suitable cellulose- or polypropylene-based material. When heated, the separator material may release one or more volatile compounds. The volatile compounds may include nicotine or flavour compounds such as tobacco or other flavouring.

The aerosol generating article may further comprise any type of solid or semi-solid material downstream of the capacitor in an aerosol flow path. Example types of solid or semi-solid material include crumb, powder, granules, pellets, shreds, strands, particles, gel, strips, loose leaves, cut filler, porous material, foam material or sheets. The material may comprise plant derived material and in particular, may comprise tobacco material. The aerosol generated by heating the electrolyte of the capacitor will flow through the solid or semi-solid material, which may be positioned between the capacitor and a filter segment or mouthpiece through which the user inhales the aerosol, for example. The solid or semi-solid material may release one or more volatile compounds which may add flavour and nicotine to the aerosol, for example. Any heating provided by the capacitor also heats or warms the solid or semi-solid material which may promote the release of volatile compounds.

The aerosol that is inhaled by the user consists essentially of the vapourised or aerosolised electrolyte and optionally one or more volatile compounds that may be released by the separator material and/or the downstream solid or semi-solid material.

The capacitor may have any suitable construction such as a spiral wound (or “jelly roll”) construction that may be substantially cylindrical or flattened so that it has more of a cuboid shape that might be more suitable for a flat-format article, a prismatic construction, a folded or serpentine construction, or a stacked construction, for example.

In one embodiment a layered capacitor substrate may comprise a first electrode, a separator adjacent the first electrode, and a second electrode adjacent the separator, i.e., so that the separator is sandwiched between the first and second electrodes, and more particularly between a pair of carbon-based electrode layers. The first electrode may be a positive electrode and the second electrode may be a negative electrode or vice versa. Such a substrate may be rolled or folded into a suitable shape while maintaining an air gap or other dielectric separation between facing electrodes or different parts of the same electrode. Dielectric separation in addition to that provided by the separator may be provided by one or more layers of dielectric material, for example. The dielectric material may comprise any suitable material. The dielectric material may comprise a plant derived material and in particular may comprise a tobacco material, for example, a porous tobacco sheet, or it may comprise any suitable cellulose- or polypropylene-based material. When heated, the dielectric material may release one or more volatile compounds. The volatile compounds may include nicotine or flavour compounds such as tobacco or other flavouring. The dielectric material and the separator material may be the same or different.

In another embodiment a layered capacitor substrate may comprise a first electrode, a first separator adjacent the first electrode, a second electrode adjacent the first separator, i.e., so that the first separator is sandwiched between the first and second electrodes and more particularly between a pair of carbon-based electrode layers, and a second separator adjacent the second electrode. The second electrode is sandwiched between the first and second separators. The first electrode may be a positive electrode and the second electrode may be a negative electrode or vice versa. Such a substrate is particularly suitable for a spiral wound (or “jelly roll”) construction, which may be substantially cylindrical or may be flattened so that it has more of a cuboid shape. Dielectric separation between the turns of the spiral wound capacitor is provided by the second separator, which in the wound substrate may be sandwiched between the first and second electrodes and more particularly between a pair of carbon-based electrode layers.

In yet another arrangement a layered capacitor substrate may comprise a plurality of first electrodes, a plurality of second electrodes, and a plurality of separators. The first electrodes may be positive electrodes and the second electrodes may be negative electrodes, or vice versa. The first and second electrodes are stacked alternately such that the substrate comprises a first electrode, a second electrode, a first electrode, a second electrode etc. in a stacking direction. A separator is sandwiched between each pair of electrodes and more particularly between a pair of carbon-based electrode layers to provide dielectric separation. Such a substrate may be useful for a flat-format article. The first electrodes may be electrically connected together and the second electrodes may be electrically connected together. The first electrodes may be electrically connected to a first capacitor terminal and the second electrodes may be electrically connected to a second capacitor terminal.

The capacitor may be contained within a casing. More particularly, the casing may contain the capacitor substrate which includes the electrodes, separator etc., and the electrolyte. The electrolyte may be injected into the casing during manufacture or if the capacitor needs to be re-filled. The casing may electrically insulate the capacitor and may be formed of any suitable material or materials.

The casing may include a paper wrapper with a metal or polymer coating, for example. The casing may include a pair of end caps of any suitable material. The casing may comprise appropriate perforations or openings, or incorporate a suitable aerosol-permeable membrane material, so that the aerosol generated when the electrolyte is heated may be freely inhaled by the user, while also preventing leakage of the electrolyte when in a liquid or gel state. The aerosol generating article may include a filter segment, for example comprising cellulose acetate fibres, at a proximal end of the aerosol generating article. The filter segment may constitute a mouthpiece filter. One or more vapour collection regions, cooling regions, and other structures may also be included in some designs. The vapour cooling region may advantageously allow the vapour to cool and condense to form an aerosol with suitable characteristics for inhalation by a user, for example through the filter segment. In general terms, a vapour is a substance in the gas phase at a temperature lower than its critical temperature, which means that the vapour may be condensed to a liquid by increasing its pressure without reducing the temperature, whereas an aerosol is a suspension of fine solid particles or liquid droplets, in air or another gas. It should, however, be noted that the terms ‘aerosol’ and ‘vapour’ may be used interchangeably in this specification.

The capacitor will preferably be pre-charged in the packaged article, i.e., it will already be charged when it is purchased by the user and before it is removably inserted into an aerosol generating device. Pre-charging the capacitor reduces the amount of energy that is required from the power source of the device for heating. This may lead to a reduction in the size and weight of the device.

An aerosol generating device may be adapted to receive, in use, the aerosol generating article as described above. The aerosol generating device may comprise an external circuit (e.g., a switching circuit) that is electrically connected between the pair of electrodes or capacitor terminals when the aerosol generating article is received in the device. The switching circuit may be configured to control the discharging of the capacitor. The switching circuit may optionally also be configured to control the charging of the capacitor from a power source of the aerosol generating device such as a battery. The switching circuit may include a switching device which may be controlled by a controller to selectively provide a continuous or switched (i.e., a discontinuous or intermittent) short circuit path between the pair of electrodes or capacitor terminals that allows the electrical charge stored in the capacitor to be discharged through the switching circuit. The switching device may include one or more switches. The one or more switches may be semiconductor switching devices, which may be connected as a bridge circuit or a converter circuit, for example. The one or more switches may be opened or closed or switched on and off by a controller to provide the short circuit path.

The switching circuit may include a first terminal that is electrically connected to the first electrode or terminal of the capacitor and a second terminal that is electrically connected to the second electrode or terminal of the capacitor when the aerosol generating article is received in the aerosol generating device. Prior to the aerosol generating article being inserted into the device, to prevent accidental or deliberate discharge of a pre-charged capacitor, it is preferred that at least one of the electrodes or terminals of the capacitor is inaccessible to the user. For example, one or both of the capacitor electrodes or terminals may be concealed within a casing of the aerosol generating article and are only made accessible for electrical connection with the terminals of the switching circuit after the aerosol generating article has been inserted into the aerosol generating device, or as it is in the process of being inserted. The electrical connection may require the casing to be ruptured at one or more locations and the aerosol generating device may include suitable means for rupturing, puncturing or tearing the casing. The first terminal of the switching circuit may be electrically connected directly to the first electrode at one or more locations, or may be electrically connected to a first capacitor terminal which is electrically connected in turn to the first electrode(s). Similarly, the second terminal of the switching circuit may be electrically connected directly to the second electrode at one or more locations, or may be electrically connected to a second capacitor terminal, which is electrically connected in turn to the second electrode(s). The capacitor terminals may be located anywhere on the aerosol generating article, e.g., near an end cap or a side of the article. The insertion orientation of the aerosol generating article into the aerosol generating device may be restricted to ensure correct alignment between the respective terminals so as to provide a reliable electrical connection between the capacitor and the external switching circuit.

The terminals of the switching circuit may be formed as rupturing devices that are designed to rupture, puncture or tear the casing and make an electrical connection with the electrodes or terminals of the capacitor. The rupturing devices may be fixed or stationary to the aerosol generating device and may be designed to rupture, puncture or tear the casing as the aerosol generating article is inserted into the device, e.g., into an aerosol generating space or heating chamber. The rupturing devices may also be movable. For example, in one arrangement the rupturing devices may be mounted on a panel or door of the aerosol generating device which is opened or removed to allow the aerosol generating article to be inserted and where the rupturing devices are designed to rupture, puncture or tear the casing when the panel or door is closed by the user. The panel or door may be hinged, for example. In another arrangement, the rupturing devices may be moved by a suitable actuator such as an electric motor or a piston, for example, that can force the rupturing devices through the casing and make an electrical connection. The rupturing devices may be moved through openings or slots in the part of the aerosol generating device that defines the aerosol generating space or heating chamber. The rupturing devices may have any suitable shape and may, for example, be formed as a needle type or crown type with one or more pointed ends, a blade type with an edge, or a punch type with a non-pointed end. The rupturing devices may be designed to work with any of the capacitor constructions mentioned above. If one of the electrodes or terminals of the capacitor is accessible, only one rupturing device may be needed.

Discharging a pre-charged capacitor through an external circuit such as a switching circuit of the aerosol generating device will generate heat in the electrodes, which in turn heats the electrolyte in which the electrodes are immersed. Sufficient heating of the electrolyte will generate an aerosol to be inhaled by the user during a vaping session. To provide improved heating, the internal resistance of the capacitor may be increased by increasing the thickness of the separator between the oppositely charged electrodes. This may result in a capacitor having fewer turns or folds if the overall dimensions remain the same. Using the external circuit to charge the capacitor will also generate heat in the electrodes, which in turn heats the electrolyte to generate an aerosol to be inhaled.

The discharging and the optional charging of the capacitor, and hence the heating of the electrolyte, may be controlled using a switching circuit, which may be part of an aerosol generating device. The aerosol generating device may also include an external heater for heating the capacitor to generate an aerosol for inhalation by the user. Put another way, heating of the electrolyte is not limited to the heat generated by the capacitor when it is discharged or charged, but the capacitor may be heated by an external heater in a similar way to a conventional aerosol generating material or substrate. Such heating will still heat the electrolyte to generate an aerosol to be inhaled. Using an external heater may provide more controllable heating during certain phases of a vaping session and thereby optimise the experience of the user. Any suitable heater may be used, e.g., a low power thin film heater, printed heater etc. The heat generated by discharging the capacitor may be used during an initial pre-heating phase and the external heater may be used to heat the electrolyte to generate an aerosol during a subsequent heating or vaping phase, for example. The power for pre-heating may therefore be provided at least in part by the capacitor and not by the power source of the aerosol generating device. This may result in a smaller power source, and hence in a smaller and lighter device. Alternatively, the electrolyte may be heated during the subsequent heating or vaping phase by cycled charging and discharging of the capacitor. During the heating or vaping phase, there may be times when heating is not needed and therefore the capacitor does not need to be discharged or charged. When heating is needed, the capacitor may be discharged or charged continuously, or it may be discharged or charged intermittently using an appropriate duty cycle, for example. In this alternative embodiment, the external heater may be used to heat the electrolyte during the initial pre-heating phase. A pre-heating phase may generally be intended to pre-heat the electrolyte to a target temperature, and the heating or vaping phase may be generally intended to heat the electrolyte for a longer period during which an aerosol is generated. If an external heater is not required, because heating may be provided entirely by the capacitor, the cost of the aerosol generating device may be reduced and the overall design may be simplified.

If the heating may be provided entirely by the capacitor, the aerosol generating article may be formed as a single-use or disposable device that does not need to be inserted into another device. In other words, the aerosol generating article may include an external circuit, e.g., a switching circuit, for controlling the discharging of the capacitor, and any other components necessary for a properly functioning single-use or disposable device.

The amount of electrolyte may be estimated or determined by the controller using any suitable method, for example using one or more electrical parameters of the capacitor. The one or more electrical parameters of the capacitor will be electrical parameters that are known to vary with the amount of electrolyte such as internal resistance and capacitance, for example. These parameters are directly proportional to the surface contact area between the electrolyte and the electrodes of the capacitor.

For example, the internal resistance R_{DC} of the capacitor may be estimated or determined from:

$${R}_{D C} = \frac{Δ V}{I}$$

where ΔV is the initial voltage step when the capacitor is discharged or charged and I is the discharging or charging current, which is normally constant.

The capacitance C of the capacitor may be estimated or determined from:

$$C = \frac{I \cdot ( {t}_{2} - {t}_{1} )}{( {V}_{2} - {V}_{1} )}$$

where t₁ and t₂ are the discharging or charging times when the voltages are V₁ and V₂, respectively. Only a small voltage difference is needed to estimate or determine the capacitance of the capacitor. The capacitance of the capacitor may also be estimated or determined by integrating the discharging or charging current (“coulomb counting”).

In a conventional capacitor, the amount of electrolyte remains constant because the electrolyte is contained within a hermetically sealed casing. But in an aerosol generating article according to the present disclosure, the electrolyte will be inhaled by the user as an aerosol over the course of a vaping session and so the amount of electrolyte will gradually decrease. The one or more electrical parameters will therefore also vary during a vaping session as the amount of electrolyte decreases. Other factors such as the temperature of the capacitor may also affect how the one or more electrical parameters of the capacitor vary and may be taken into account when the one or more electrical parameters are used to estimate or determine the amount of electrolyte. By monitoring the amount of electrolyte, and notifying this to the user, the user is better informed about how much electrolyte is remaining in the capacitor over the course of a vaping session, and is consequently able to work out for how much longer a particular aerosol generating article is likely to be able to generate an aerosol.

The one or more electrical parameters of the capacitor may be estimated or determined using at least one of voltage and current measurements obtained when the capacitor is discharged or charged through an external circuit as described above. For example, the voltage and current measurements may be obtained from voltage and current sensors when the capacitor is being discharged or charged. The voltage and current sensors may be part of a determining circuit of the aerosol generating device that provides measurements to the controller. Estimating or determining the one or more electrical parameters of the capacitor may also use a time measurement, e.g., the time taken to discharge or charge the capacitor while the current and voltage measurements are being obtained. The time taken to discharge or charge the capacitor between predefined upper and lower limits is known to vary with the amount of electrolyte, in particular, the time taken to discharge or charge the capacitor will typically decrease as the amount of remaining electrolyte decreases during the vaping session.

The amount of electrolyte may be estimated or determined by carrying out one or more amount determining steps. In each determining step, one or more of the voltage, current and time measurements may be obtained while the capacitor is discharged or charged. More particularly, in an initial determining step an initial amount of electrolyte in the capacitor is estimated or determined by the controller, e.g., at the start of a vaping session. In one or more subsequent steps during the vaping session, the amount of electrolyte remaining in the capacitor is estimated or determined by the controller. The amount of electrolyte remaining in the capacitor is notified to the user by controlling the visual indicator. The subsequent steps may be carried out at regular or irregular intervals or in response to a puff detection, i.e., after the user has inhaled the generated aerosol. This may help the user to understand how much electrolyte is remaining in the capacitor after a puff has been taken.

The visual indicator may comprise one or more light emitters (e.g., light emitting diodes (LEDs)).

The controller may be adapted to change one or both of the colour (i.e., the wavelength) and intensity of the light emitted by each light emitter based on the amount of electrolyte estimated or determined by the controller. For example, the colour of the visual indicator may change and/or the intensity of the emitted light may decrease or increase as the amount of electrolyte remaining in the capacitor gradually decreases. If the user starts a vaping session when the capacitor is only partly full, the appropriate colour and/or intensity may be selected by the controller. A predefined colour may be used to notify the user that the amount of electrolyte is below a minimum amount—i.e., the capacitor is empty or almost empty. In other words, when the amount of electrolyte has fallen below a minimum amount, the controller may be adapted to change the colour of the light emitted by each light emitter to the predefined colour so that the user is notified that the capacitor is empty or almost empty and that the aerosol generating article may need to be replaced or re-filled. The controller may also be adapted to change the intensity to a predefined intensity—e.g., a maximum intensity—when the amount of electrolyte is below a minimum amount. Predefined colours may also be used to notify the user about other operating conditions of the aerosol generating system such as if the aerosol generating article has been incorrectly inserted into the aerosol generating device, or if it is damaged or is not genuine, or if there is a fault with the aerosol generating device, for example. The predefined colours may customisable or selectable by the user.

The controller may be adapted to control each light emitter to blink, i.e., to emit light intermittently. The controller may be adapted to change the frequency at which each light emitter blinks based on the amount of electrolyte estimated or determined by the controller. For example, each light emitter may be controlled to blink faster or slower as the amount of electrolyte remaining in the capacitor gradually decreases. If the user starts a vaping session when the capacitor is only partly full, the appropriate frequency may be selected by the controller. Changing the frequency at which each light emitter blinks may be combined with a change in one or both of the colour and intensity of the light emitted by each light emitter.

The controller may be adapted to control each light emitter to blink if the amount of electrolyte estimated or determined by the controller is below a predefined threshold—for example, a threshold that is indicative of a maximum amount of electrolyte so that if blinking occurs the user knows that the aerosol generating article has already been partly used. This may be useful if the user starts a vaping session with an aerosol generating article that has been used previously so the amount of electrolyte is less than the maximum amount. The controller may be adapted to control each light emitter not to blink—i.e., the emit light constantly—if the amount of electrolyte estimated or determined by the controller is above the predefined threshold so that the user knows that the capacitor is full or almost full. The predetermined threshold may also be a threshold that is indicative of a minimum amount of electrolyte so that if blinking occurs the user knows that the capacitor is empty or almost empty and that the aerosol generating article may need to be replaced or re-filled. The blinking may be combined with a change to a predefined colour or intensity of light emitted by each light emitter, for example, that also indicates that the capacitor of the aerosol generating article is almost empty.

The visual indicator may comprise one or more sections or panels that may be lit independently by the one or more light emitters. The one or more light emitters may be positioned behind the one or more sections or panels, for example, and each section or panel may be transparent or translucent—i.e., made of any suitable light-transmitting material. Each section or panel may be formed as part of an outer housing or body of the aerosol generating device. Each section or panel may be defined by a single light emitter or a group of light emitters. If the visual indicator comprises a plurality of sections or panels, the controller may be adapted to control each light emitter to light up a predefined number of sections or panels based on the amount of electrolyte estimated or determined by the controller. For example, the visual indicator may comprise a plurality of sections or panels arranged in a suitable pattern which are all lit when the amount of electrolyte is above a maximum amount—i.e., the capacitor is full or almost full. As the amount of electrolyte decreases, the number of sections or panels that are lit may decrease. When the amount of electrolyte is below a minimum amount—i.e., capacitator is empty or almost empty-just one or none of the sections or panels may be lit. If the user starts a vaping session when the capacitor is only partly full, the appropriate number of sections or panels will be lit by the controller. For example, if the amount of electrolyte estimated or determined by the controller is about half of the maximum amount when the vaping session starts, the controller may be adapted to control the one or more light emitters to light half of the sections or panels. Lighting up an appropriate number of sections or panels may be combined with changing one or both of the colour and intensity of the light emitted by each light emitter, blinking, the use of predefined colours etc. For example, when just one of the sections or panels is lit, the one or more light emitters that are used to light that section or panel may be controlled to blink and/or emit a predefined colour or intensity of light so that the user knows that the capacitor is empty or almost empty and that the aerosol generating article may need to be replaced or re-filled.

The visual indicator may be positioned anywhere on the aerosol generating device, but may preferably be visible when the device is being held in the hand of the user. The visual indicator may have any suitable shape or size.

In one embodiment, the visual indicator may be formed in the shape of a ring, e.g., as an annular indicator. The ring may comprise a plurality of sections or panels-see above. If the aerosol generating device includes an opening for receiving the aerosol generating article, the visual indicator may substantially surround the opening. For example, if the aerosol generating article is substantially cylindrical, and the aerosol generating device includes a substantially cylindrical opening for receiving the aerosol generating article so that it may be inserted into the device, e.g., into an aerosol generating space or heating chamber, the visual indicator may be arranged around the opening. The visual indicator may therefore be visible to the user when inhaling an aerosol from the proximal end of the aerosol generating article, e.g., through a mouthpiece or filter section.

The visual indicator may be a display screen, e.g., liquid crystal or LED display screen. The controller may be adapted to control the display screen to display information directly indicative of the amount of electrolyte estimated or determined by the controller—e.g., an absolute value or a percentage where 100% indicates that the capacitor is full and 0% indicates that the capacitor is empty. The controller may also be adapted to control the display screen to display the remaining duration of the vaping session (in minutes or seconds, for example) or the remaining number of puffs, which may both be estimated or determined from the amount of electrolyte. The remaining duration of the vaping session may depend on the vaping pattern of the user—i.e., if the user takes strong puffs with short gaps between puffs, the electrolyte will be depleted more quickly and the duration of the vaping session may be estimated based on the amount of remaining electrolyte and then displayed to the user on the display screen. The display screen may also display information graphically such as by displaying one or more blocks of colour whose size, shape or colour is indicative of the amount of electrolyte. Other graphical displays may also be used.

According to a second aspect of the present disclosure there is provided a method of visually indicating to a user the amount of electrolyte in a capacitor of an aerosol generating article, wherein the electrolyte, when heated, generates an aerosol for inhalation by a user. In other words, this may be a method of visually indicating to the user the amount of aerosolisable electrolyte remaining in the capacitor of the aerosol generating article. The method comprises controlling a visual indicator of an aerosol generating device adapted to receive, in use, the aerosol generating article, based on the amount of electrolyte.

The visual indicator may comprise one or more light emitters as described herein. The method may comprise one or both of:
changing one or both of the colour and intensity of the light emitted by each light emitter based on the amount of electrolyte, and
changing the frequency at which each light emitter blinks based on the amount of electrolyte.

The visual indicator may comprise a plurality of sections or panels as described herein. The method may comprise lighting up a predefined number of sections or panels based on the amount of electrolyte. The sections or panels may be lit up by controlling the one or more light emitters, for example.

The visual indicator may be a display screen as described herein, e.g., a liquid crystal or LED display screen. The method may comprise displaying information on the display screen that is directly or indirectly indicative of the amount of electrolyte. For example, the display screen may be controlled to display the remaining duration of the vaping session (in minutes or seconds, for example), or the remaining number of puffs, which may both be estimated or determined from the amount of electrolyte.

In the above-mentioned aspects of the present disclosure, the aerosol generating article (or consumable) functions as a capacitor where the electrolyte is aerosolisable, or where the aerosol generating article has an energy storage function. In alternative aspects of the present disclosure, the aerosol generating article may comprise aerosolisable humectant, i.e., a material which is capable of being converted into an aerosol by heating or by electrolysis, which aerosol is then inhaled by the user. Such humectant does not necessarily also function as an electrolyte—in other words, the aerosol generating article does not have to include or function as a capacitor. The purpose of the aerosolisable humectant is to provide an inhalable aerosol without necessarily additionally providing any energy storage function as an electrolyte. According to a third aspect of the present disclosure there is provided an aerosol generating system comprising:
an aerosol generating article (or consumable) comprising aerosolisable humectant; and
an aerosol generating device adapted to receive, in use, the aerosol generating article, the aerosol generating device comprising:
a visual indicator; and
a controller adapted to:
   estimate or determine the amount of humectant in the aerosol generating article; and
   control the visual indicator based on the amount of humectant, i.e., so as to visually indicate to the user the amount of humectant remaining in the aerosol generating article.

The amount of humectant will decrease over the course of a vaping session.

The visual indicator may be generally as described herein, e.g., it may comprise one or more light emitters or be formed as a display screen. Such light emitters may be controlled as described herein, e.g., to change the colour and/or intensity of the emitted light, frequency of blinking etc. depending on the amount of humectant. The display screen may be controlled to display information that is directly or indirectly indicative of the amount of humectant estimated or determined by the controller.

The aerosol generating article may comprise an aerosol generating material or substrate that is heated, without burning, to volatise at least one component of the aerosol generating material and thereby generate an aerosol for inhalation by a user of the aerosol generating device. The aerosol generating article may comprise a body of aerosol generating material. The aerosol generating material may be any type of solid or semi-solid material. Example types of solid or semi-solid material include crumb, powder, granules, pellets, shreds, strands, particles, gel, strips, loose leaves, cut filler, porous material, foam material or sheets. The aerosol generating material may comprise plant derived material and in particular tobacco material.

The aerosol generating material may comprise an aerosol-former—i.e., the humectant may be aerosol-former. Examples of aerosol-formers include polyhydric alcohols and mixtures thereof such as glycerine or propylene glycol. In other possible examples, the aerosol-former may include other alcohols, such as ethanol, 1,3-propanediol, or may include water. The aerosol-former can be selected from a polyol such as sorbitol, glycerol, and glycols like propylene glycol or triethylene glycol: a non-polyol such as monohydric alcohols, acids such as lactic acid, glycerol derivatives, esters such as triacetin, triethylene glycol diacetate, triethyl citrate, glycerin or vegetable glycerin. Typically, the aerosol generating material may comprise an aerosol-former content of between approximately 5% and approximately 50% on a dry weight basis of the aerosol generating material. In some embodiments, the aerosol generating material may comprise an aerosol-former content of between approximately 10% and approximately 20% on a dry weight basis of the aerosol generating material, and possibly approximately 15% on a dry weight basis of the aerosol generating material. The aerosol generating material may comprise an ionic conductivity improvement agent such as sodium chloride or an ionic liquid.

Also, the aerosol generating material may be the aerosol-former itself. In this case, the aerosol generating material may be a liquid. Also, in this case, the aerosol generating article may include a liquid retaining substance (e.g., a bundle of fibres, porous material such as ceramic, etc.) which retains the liquid to be aerosolised and allows an aerosol to be formed and released from the liquid retaining substance, for example towards an outlet for inhalation by a user.

It will therefore be understood that the aerosolisable humectant may be the aerosol-former described above, or in a specific case, it may be electrolyte if the aerosol generating article comprises or functions as a capacitor such as an electric double-layer supercapacitor, for example. Any reference herein to electrolyte in the description may be considered to be a reference to any suitable aerosolisable humectant such as aerosol-former if appropriate. If the humectant is aerosol-former, and the aerosol generating article does not comprise a capacitor, the amount of humectant may be estimated or determined by the controller using any suitable method, for example using one or more electrical parameters that are known to vary with the amount of humectant such as resistance or capacitance (e.g., by measuring one or more of resistive, capacitive or electrical load). Such electrical parameters might be measured using a pair of spaced electrodes, for example. At least part of the aerosol generating material or liquid retaining substance may be received between the electrodes.

### BRIEF DESCRIPTION OF THE DRAWINGS

FIG. 1 is a diagrammatic view of a first example of an aerosol generating article:

FIG. 2 is a diagrammatic view of a first example of a capacitor having a spiral wound construction:

FIG. 3 is a cross section view along line A-A of FIG. 2:

FIG. 4 is a diagrammatic view of an aerosol generating device:

FIG. 5 is a schematic representation of a switching circuit;

FIG. 6 is a representation of a temperature profile during a pre-heating and heating phase:

FIG. 7 is a representation of discharging and charging a capacitor during an electrolyte amount determining step:

FIG. 8 is a diagrammatic view of a first example of a visual indicator as part of the aerosol generating device:

FIGS. 9A to 9E are diagrammatic views of the first example of the visual indicator of FIG. 8 showing different colours of emitted light:

FIG. 10 is a diagrammatic view of a second example of a visual indicator as part of the aerosol generating device;

FIGS. 11A to 11E are diagrammatic views of the second example of the visual indicator of FIG. 10 showing different numbers of lit sections; and

FIG. 12 is diagrammatic view of a third example of a visual indicator as part of the aerosol generating device.

### DETAILED DESCRIPTION OF EMBODIMENTS

Embodiments of the present disclosure will now be described by way of example only and with reference to the accompanying drawings.

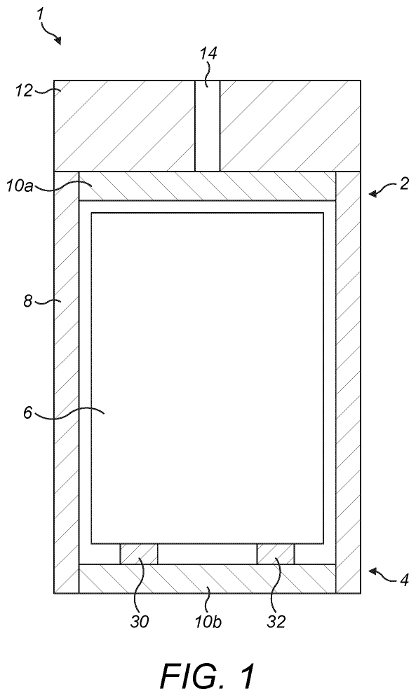

Referring initially to FIG. 1, there is shown diagrammatically an example of an aerosol generating article 1. The article 1 has a proximal end 2 and a distal end 4.

The article 1 includes a capacitor 6 that includes an electrolyte. The capacitor 6 is surrounded by a paper wrapper 8 with a metal or polymer coating. An end cap 10a, 10b is provided at each end of the capacitor 6. The paper wrapper 8 and the end caps 10a, 10b define an outer casing for the capacitor 6 that contains the electrolyte and provides electrical insulation.

The article 1 is generally cylindrical.

At the proximal end 2, the article 1 includes a mouthpiece 12 having an outlet 14 through which a user may inhale an aerosol that is generated by heating the electrolyte. Although not shown, the proximal end cap 10a may include appropriate perforations or openings, or incorporate a suitable aerosol-permeable membrane material, so that the generated aerosol may pass through the end cap to the outlet 14.

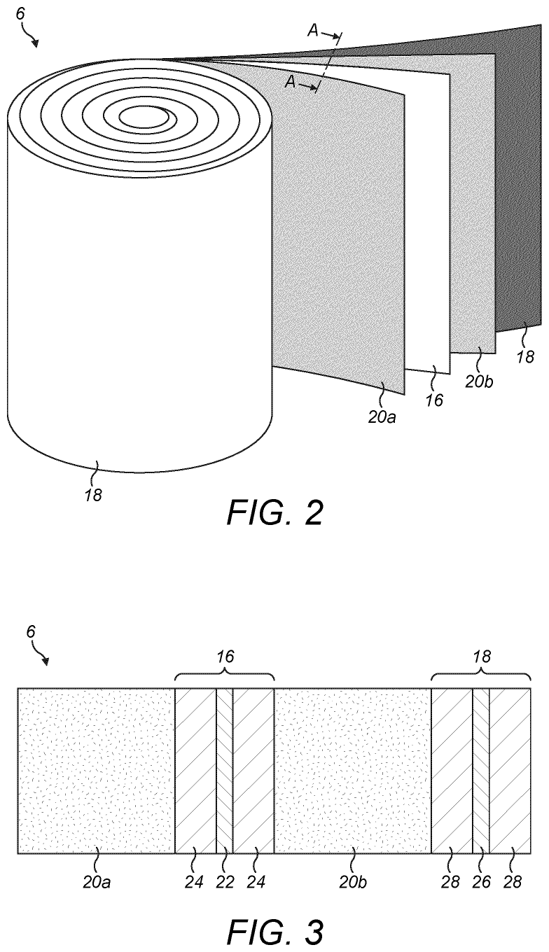

Referring to FIG. 2, the capacitor 6 is an electric double-layer supercapacitor and has a generally cylindrical, spiral wound (or “jelly roll”) construction. The capacitor 6 includes a positive electrode 16 and a negative electrode 18. The electrodes 16, 18 are separated by a pair of porous separators 20a, 20b. As shown more clearly in FIG. 3, the positive electrode 16 includes a positive current collector 22. Each side of the positive current collector 22 is provided with a porous carbon-based electrode layer 24 such as a layer of porous charcoal material or activated carbon, for example. The negative electrode 18 includes a negative current collector 26. Each side of the negative current collector 24 is provided with a porous carbon-based electrode layer 28 such as a layer of porous charcoal material or activated carbon, for example. The positive and negative current collectors 22, 26 are aluminium foil layers, for example.

The separators 20a, 20b are formed from a tobacco material such as a porous tobacco sheet which releases volatile compounds when it is heated. In an alternative arrangement, which is not shown, the separators may be formed from a suitable cellulose- or polypropylene-based material and the electrolyte may flow through a tobacco material such as crumb tobacco that is downstream of the capacitor in an aerosol flow path. The tobacco material may be positioned between the capacitor and the mouthpiece. The tobacco material adds flavour and nicotine to the aerosol. The heating provided by the capacitor also heats or warms the tobacco material, which promotes the release of volatile compounds. Instead of the tobacco material, a flavour source without nicotine may be used.

The electrodes 16, 18 and the separators 20a, 20b are immersed in an electrolyte which permits cation and anion migration when the capacitor 6 is charged or discharged, and generates an aerosol for inhalation by the user when it is heated. The electrolyte may comprise sodium chloride and glycerol, and optionally polyvinyl alcohol as a gelling agent. But other non-toxic or food-grade electrolytes may also be used. The capacitor 6 is pre-charged during the manufacturing process and is packaged and sold to the user in a pre-charged state.

The article 1 includes a positive capacitor terminal 30 which is electrically connected to the positive electrode 16, i.e., to the positive current collector 22 at one or more locations, and a negative capacitor terminal 32 which is electrically connected to the negative electrode 18, i.e., to the negative current collector 26, at one or more locations. The capacitor terminals 30, 32 may be located inside the outer casing of the article 1 so that they are not accessible to the user. This helps to prevent the accidental or deliberate discharge of the capacitor 6 before the article is removably inserted into an aerosol generating device preparatory to starting a vaping session.

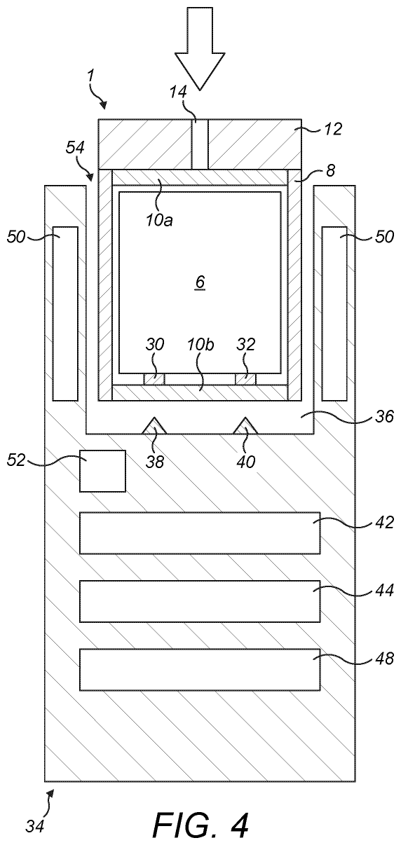

FIG. 4 shows an aerosol generating device 34 adapted to receive the aerosol generating article 1. The device 34 includes a cavity 36 into which the article 1 may be inserted.

The device 34 includes a pair of rupturing devices 38, 40 that are adapted to rupture the distal end cap 10b of the article 1 when it is inserted into the cavity 36. The angular orientation of the article 1 relative to the device 34 may be restricted when it is inserted into the cavity 36 so that the rupturing device 38 makes an electrical connection with the positive electrode 30 and the rupturing device 40 makes an electrical connection with the negative electrode 32. Other ways of ensuring a reliable electrical connection may be used. For example, the positive and negative terminals of the article may have an annular construction and be located coaxial with each other so that appropriately positioned rupturing devices will make electrical contact with the terminals irrespective of the angular orientation of the article relative to the device.

The device 34 includes a switching circuit 42 and a power source 44 such as a battery.

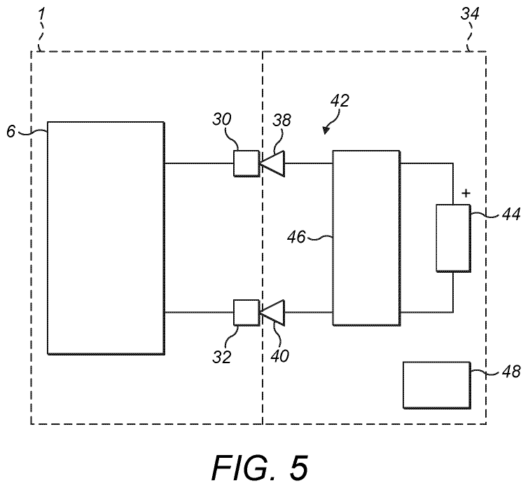

An example of a switching circuit 42 is shown in FIG. 5. The switching circuit 42 includes the rupturing devices 38, 40 which function as positive and negative terminals and are electrically connected to the positive and negative terminals 30, 32 of the article 1 when it is properly received in the cavity 36. The switching circuit 42 includes a switching device 46 that may be operated by a controller 48 to control the discharging of the capacitor 6 through the switching circuit 42. The controller 48 may include at least one microcontroller unit (MCU) or microprocessor unit (MPU), for example.

After the article 1 has been inserted into the device 34, the capacitor 6 may be discharged by controlling the switching device 46 to provide a continuous or switched short circuit path between the positive and negative terminals 30, 32 of the article 1, and hence between the positive and negative electrodes 16, 18 of the capacitor 6. The short circuit path between the positive and negative terminals 30, 32 is formed via the switching device 46. Additionally, the switching device 46 may comprise a resistor to prevent over-discharge current or an electrical load to enable constant current discharge. If the discharging current is kept to a predetermined value, the current sensor mentioned below may be omitted. Discharging the capacitor 6 through the switching circuit 42 dissipates heat in the electrodes 16, 18. This heats the electrolyte and generates an aerosol that may be inhaled by the user through the outlet 14 in the mouthpiece 12. Pre-charging the capacitor 6 reduces the amount of energy that is required from the power source 44 of the device for heating. This may lead to a reduction in the overall size and weight of the device 34. In particular, the size and weight of the power source 44 may be reduced. This is significant because the power source is often the largest and heaviest component of the device 34. In some cases, the energy for heating may be provided entirely by the capacitor 6 and the power source 44 may be eliminated or reduced to providing power for other components of the device such as the controller, for example. But in other cases, the energy provided by the capacitor 6 will be used to supplement or partially replace the energy provided by the power source 44.

The capacitor 6 may also be charged from the power source 44 by controlling the switching device 46 (or a separate switching device of the switching circuit, which is not shown). Charging the capacitor 6 also dissipates heat in the electrodes 16, 18, which heats the electrolyte and generates an aerosol that may be inhaled by the user through the outlet 14 in the mouthpiece 12. Heat may therefore be generated repeatedly charging the capacitor 6 from the power source 44 and subsequently discharging the capacitor through the switching circuit 42.

The switching device 46 which can be used to enable the above-mentioned discharging and charging of the capacitor 6 may comprise one or more switches, for example. A discharging switch for controlling the discharging current of the capacitor 6 may be connected in series between the rupturing devices 38, 40 that define positive and negative terminals of the switching circuit 42. A charging switch for controlling the charging current of the capacitor 6 may be connected in series between rupturing device 38 that defines the positive terminal of the switching circuit 42 and a positive terminal of the power source 44 and/or in series between the rupturing device 40 that defines the negative terminal of the switching circuit 42 and a negative terminal of the power source. The switches may be semiconductor switching devices, e.g., transistors.

Although not shown, the device 34 may include a current sensor to measure the discharging or charging current of the capacitor 6 and a voltage sensor to measure the voltage output by the capacitor. The measurements provided by the current sensor and the voltage sensor are used to determine the electrical parameter of the capacitor such as internal resistance or capacitance, for example.

The device 34 may optionally include one or more heaters 50. The heaters 50 may be used to heat the electrolyte in the capacitor 6 to generate an aerosol that may be inhaled by the user through the outlet 14 in the mouthpiece 12. Such heating may be used to better control the heating of the electrolyte, for example during a heating or vaping phase.

The device 34 includes a visual indicator 52 for indicating the amount of electrolyte to the user.

The amount of remaining electrolyte may be estimated or determined by the controller 48 from an electrical parameter of the capacitor 6 such as internal resistance or capacitance that are known to vary with the amount of electrolyte. The electrical parameter of the capacitor 6 may be estimated or determined using at least one of voltage, current and time measurements obtained when the capacitor 6 is discharged or charged through the switching circuit 42 as described above. For example, in the specific case where the electrical parameter is the internal resistance R_{DC} of the capacitor 6 it may be estimated or determined from:

$${R}_{D C} = \frac{Δ V}{I}$$

where ΔV is the initial voltage step when the capacitor 6 is discharged or charged and I is the discharging or charging current, which is kept constant.

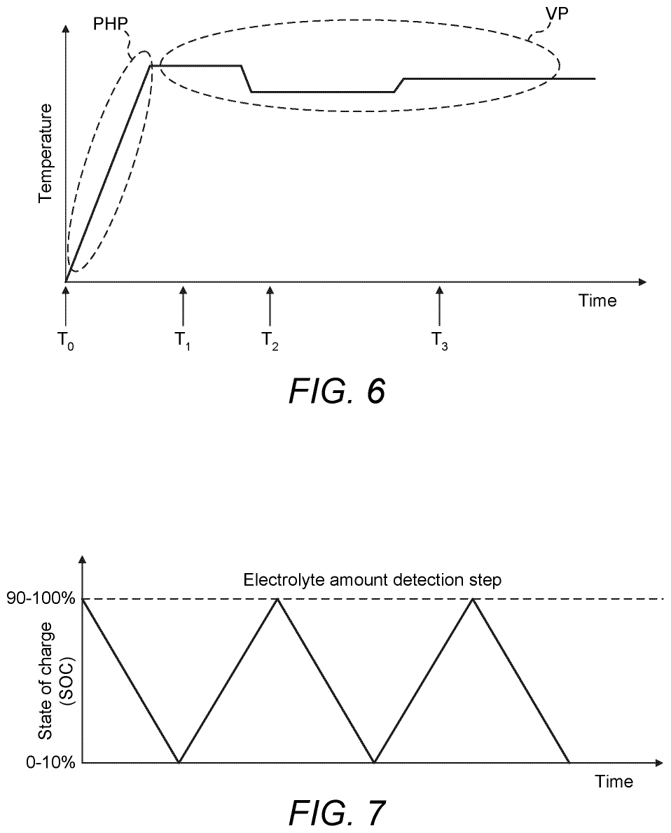

FIG. 6 is representative of a vaping session that includes a pre-heating phase PHP and a heating or vaping phase VP.

The controller 48 carries out a plurality of electrolyte amount determining steps.

In an initial step which is carried out at time T₀ before the pre-heating phase starts. an initial value V₀ of the electrical parameter of the capacitor 6 is estimated or determined. This initial value V₀ is therefore indicative of the initial amount of electrolyte in the capacitor 6 prior to the start of a vaping session. It is assumed that the initial value V₀ defines a “baseline” against which subsequent values may be compared. It is also assumed for the purposes of the following description that the initial amount of electrolyte is a maximum amount—i.e., that the capacitor 6 is full at the start of the vaping session. The visual indicator 52 may indicate to the user that the capacitor 6 is full of electrolyte.

In subsequent steps, which are carried out at times T₁, T₂ and T₃, subsequent values V₁, V₂ and V₃ of the electrical parameter of the capacitor 6 are estimated or determined. The subsequent steps are carried out during the heating or vaping phase, and may be in response to a puff detection. The subsequent steps are carried out at times when the temperature of the capacitor 6 is kept substantially constant. In other words, the subsequent steps are not carried out at times when the temperature is controlled to be decreasing or increasing.

The initial value V₀ and each respective subsequent value V₁, V₂ and V₃ are then used to estimate or determine the amount of remaining electrolyte. For example, the initial value V₀ and the first subsequent value V₁ are used to estimate or determine the amount of electrolyte at time T₁, the initial value V₀ and the second subsequent value V₂ are used to estimate or determine the amount of electrolyte at time T₂, and so on. If the electrical parameter is directly proportional to the amount of electrolyte, i.e., so that the electrical parameter decreases as the amount of electrolyte in the capacitor 6 decreases, the amount of electrolyte at a subsequent time Tᵢ may be estimated or determined by:

$$Electrolyte remaining ( \% ) = \frac{{V}_{i}}{{V}_{0}} \times 100 , i = 1 , 2 , 3 …$$

For example, if the subsequent value V₁ is three quarters of the initial value V₀, the amount of remaining electrolyte may be calculated to be 75% of the initial amount at the start of the vaping session and this may be notified to the user by the visual indicator 52. Similarly, if the subsequent values V₂ and V₃ are respectively one half and one third of the initial value of V₀, the amount of remining electrolyte may be calculated to be 50% and 33% of the initial amount at the start of the vaping session and this may be indicated to the user by controlling the visual indicator 52. It will be understood that other ways of calculating the amount of electrolyte in the capacitor 6 may be used. For example, the amount of electrolyte may be estimated or determined using a relationship between an electrical parameter of the capacitor 6 (e.g., internal resistance or capacitance) and the amount of electrolyte, or between one or more measured values of voltage, current and time and the amount of electrolyte. The relationship may be a linear or polynomial relationship, for example. In one example, the estimated or determined values V₀. V₁, V₂ etc. of the electrical parameter may correspond to amounts A₀, A₁, A₂ etc. of electrolyte according to a particular relationship. The amounts of electrolyte may be derived using a look-up table, for example.

Referring to FIG. 7, during the initial step and each subsequent step, the capacitor 6 is discharged and charged three times. Each time the capacitor 6 is discharged, a value of the electrical parameter is estimated or determined from one or more of the voltage, current and time measurements. The three values are then averaged to obtain the values V₀, V₁, . . . , V₃ mentioned above. The capacitor 6 is discharged and charged between predefined upper and lower limits, which in FIG. 6 are expressed in terms of the state of charge (SOC). In particular, the capacitor 6 is substantially fully discharged and substantially fully charged and the upper limit is a SOC of about 90-100% and the lower limit is a SOC of about 0-10%.

The discharging current of the capacitor 6 around the fully charged state tends to be large as compared with an intermediate state. The same is also true for the charging current of the capacitor 6 around the fully discharged state. Such large currents are not suitable for the above-mentioned temperature control. Consequently, when the capacitor is being discharged or charged to heat the electrolyte and generate an aerosol for inhalation by the user, i.e., at times other than when the initial step and each subsequent step are being carried out for the purpose of estimating or determining the amount of electrolyte, this discharging and/or charging is preferably carried out in a narrower range between intermediate states that are removed from the fully charged and fully discharged states. The narrower range for discharging and/or charging the capacitor to heat the electrolyte may be defined by predefined upper and lower limits. For example, if expressed in terms of SOC, the upper limit may be about 50-80% and the lower limit may be about 20-40%.

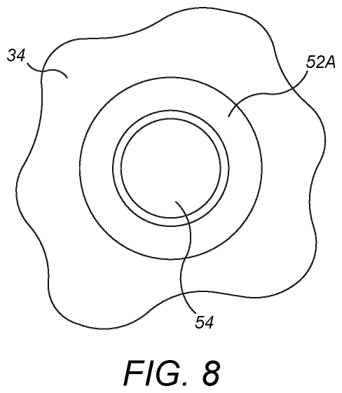

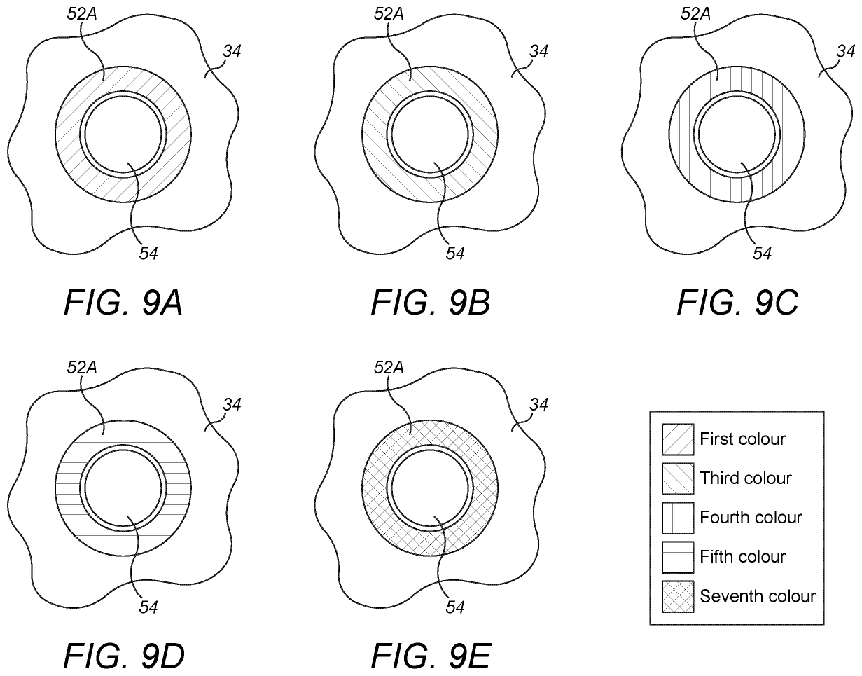

Referring to FIG. 8, a first example of a visual indicator 52A is in the form of a ring that surrounds the opening 54 in the aerosol generating device 34 into which the aerosol generating article 1 is inserted in use. The visual indicator 52A includes one or more light emitters, e.g., light emitting diodes (LEDs) that are not shown. The controller 48 is adapted to change one or both of the colour (i.e., the wavelength) and intensity of the light emitted by each light emitter based on the amount of electrolyte. The colour of the emitted light may be changed if the amount of electrolyte determined or estimated by the controller 48 falls below a series of thresholds—e.g., thresholds where the amount of electrolyte is about 95%, about 80%, about 60%, about 40%, about 20% and about 5% of the initial amount. For example, a first colour may be used for amounts of electrolyte above a threshold of about 95% of the initial amount—i.e., where the capacitor 6 is effectively full. A second colour may be used for amounts of electrolyte less than about 95% and greater than about 80% of the initial amount. A third colour may be used for amounts of electrolyte less than about 80% and greater than about 60% of the initial amount. A fourth colour may be used for amounts of electrolyte less than about 60% and greater than about 40% of the initial amount. A fifth colour may be used for amounts of electrolyte less than about 40% and greater than about 20% of the initial amount. A sixth colour may be used for amounts of electrolyte less than about 20% and greater than about 5% of the initial amount. A seventh colour may be used for amounts of electrolyte less than about 5% of the initial amount—i.e., where the capacitor 6 is effectively empty. FIGS. 9A to 9E show how the colour of the visual indicator 52A may change as the amount of electrolyte decreases during the vaping session. At the start of the vaping session (i.e., time T₀) the initial amount of electrolyte (i.e., initial value V₀ of the electrical parameter) is a maximum amount because the capacitor 6 is full and the light emitters are controlled so that the emitted light is the first colour. At time T₁ when the value V₁ is three quarters of the initial value V₀ and the amount of electrolyte is three quarters of the initial amount, the light emitters are controlled so that the emitted light is a third colour. At time T₂ when the value V₂ is half of the initial value V₀ and the amount of electrolyte is half of the initial amount, the light emitters are controlled so that the emitted light is a fourth colour. At time T₃ when the value V₃ is a third of the initial value and the amount of electrolyte is a third of the initial amount, the light emitters are controlled so that the emitted light is the fifth colour. Finally, at a time Tₙ when the amount of the electrolyte (i.e., a final value Vₙ of the electrical parameter) is a minimum amount, the light emitters are controlled so that the emitted light is the seventh colour which indicates to the user that the capacitor 6 is empty.

Instead of changing the colour of the emitted light, the controller 48 may change its intensity based on the amount of electrolyte. For example, the intensity may decrease as the amount of electrolyte decreases. In one example, the intensity may be changed to a maximum intensity when the amount of electrolyte has fallen below a minimum amount so that the user knows that the capacitor 6 is empty or nearly empty. The colour of the emitted light may also be changed to a predefined colour. The colour of the light emitted by the light emitters may also be changed by the controller 48 to a predefined colour if the aerosol generating article 1 has been incorrectly inserted into the aerosol generating device 34, or if it is damaged or is not genuine, or if there is a fault with the aerosol generating device 34, for example. The predefined colours may customisable or selectable by the user.

The controller 48 may be adapted to control the light emitters to blink, i.e., to emit light intermittently. The controller 48 may be adapted to change the frequency at which the light emitters blink based on the amount of electrolyte estimated or determined by the controller. For example, the light emitters may be controlled to blink faster or slower as the amount of electrolyte remaining in the capacitor 6 gradually decreases. The controller 48 may be adapted to control the light emitters to blink if the amount of electrolyte estimated or determined by the controller 48 is below a predefined threshold. For example, the light emitters may be controlled to blink if the amount of electrolyte is below about 5% of the initial amount. The light emitters may also be controlled to blink if the initial value is below a threshold that is indicative of a maximum amount of electrolyte so that if blinking occurs at the start of a vaping session the user knows that the aerosol generating article 1 has already been partly used.

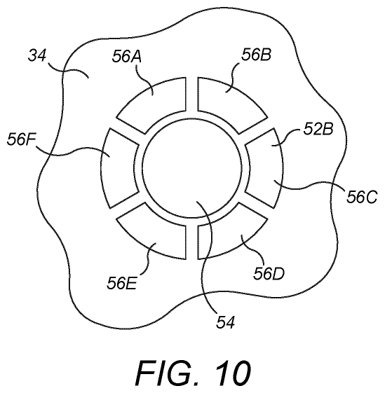

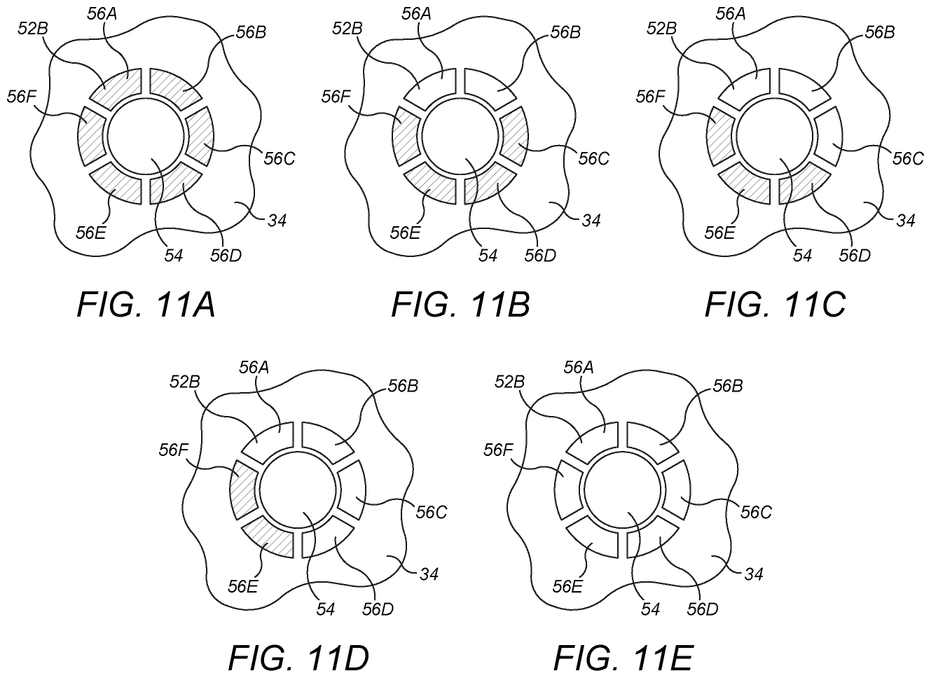

Referring to FIG. 10, a second example of a visual indicator 52B includes one or more sections or panels 56A, 56B, . . . , 56F. The visual indicator 52B is in the form of a ring that surrounds the opening 54 in the aerosol generating device 34 into which the aerosol generating article 1 is inserted in use. The visual indicator 52A includes one or more light emitters, e.g., light emitting diodes (LEDs) that are not shown. The controller 48 controls the light emitters to light up a certain number of sections or panels based on the amount of electrolyte. The number of sections that are lit up may be changed if the amount of electrolyte determined or estimated by the controller 48 falls below a series of thresholds—e.g., thresholds where the amount of electrolyte is about 95%, about 80%, about 60%, about 40%, about 20% and about 5% of the initial amount. For example, six sections may be lit up for amounts of electrolyte above a threshold of about 95% of the initial amount—i.e., where the capacitor 6 is effectively full. Five sections may be lit up for amounts of electrolyte less than about 95% and greater than about 80% of the initial amount. Four sections may be lit up for amounts of electrolyte less than about 80% and greater than about 60% of the initial amount. Three sections may be lit up for amounts of electrolyte less than about 60% and greater than about 40% of the initial amount. Two sections may be lit up for amounts of electrolyte less than about 40% and greater than about 20% of the initial amount. One section may be lit up for amounts of electrolyte less than about 20% and greater than about 5% of the initial amount. No sections may be lit up for amounts of electrolyte less than about 5% of the initial amount—i.e., where the capacitor 6 is effectively empty. FIGS. 11A to 11E show how the number of sections that are lit up may change as the amount of electrolyte decreases during the vaping session. At the start of the vaping session (i.e., time T₀) the initial amount of electrolyte (i.e., initial value V₀ of the electrical parameter) is a maximum amount because the capacitor 6 is full and the light emitters are controlled so that all six sections of the visual indicator 52B—i.e., sections 56A, 56B, . . . , 56F—are lit up. At time T₁ when the value V₁ is three quarters of the initial value and the amount of electrolyte is three quarters of the initial amount, the light emitters are controlled so that only four of the sections of the visual indicator 52B—i.e., sections 56C, . . . , 56F—are lit up. At time T₂ when the value V₂ is half of the initial value and the amount of electrolyte is half of the initial amount, the light emitters are controlled so that only three of the sections of the visual indicator 52B—i.e., sections 56D, 56E and 56F—are lit up. At time T₃ when the value V₃ is a third of the initial value and the amount of electrolyte is a third of the initial amount, the light emitters are controlled so that only two of the sections of the visual indicator 52B—i.e., sections 56E and 56F—are lit up. Finally, at a time Tₙ when the amount of the electrolyte (i.e., a final value Vₙ of the electrical parameter) is a minimum amount, the light emitters are controlled so that none of the sections of the visual indicator 52B are lit up. In other examples, one of the sections—e.g., section 56F—may be lit when the value of the electrolyte is a minimum amount and the one or more light emitters that are used to light that section may be controlled to blink so that the user knows that the capacitor 6 is empty or almost empty and that the aerosol generating article 1 may need to be replaced or re-filled. The colour emitted by the one or more light emitters may also be changed by the controller—e.g., to a predefined colour. In one example, if a vaping session is started with a capacitor 6 that is empty or almost empty, all of the segments 56A, 56B, . . . , 56F may be controlled to be lit in a predefined colour that indicates to the user that the capacitor is empty or almost empty. This may be instead of starting the vaping session without any of the segments 56A, 56B, . . . , 56F being lit.

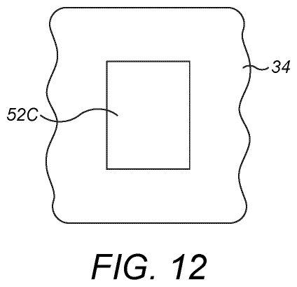

Referring to FIG. 12, a third example of a visual indicator 52C is a display screen, e.g., a liquid crystal or LED display screen. The controller 48 may be adapted to control the display screen 52C to display information directly indicative of the amount of electrolyte estimated or determined by the controller—e.g., an absolute value or a percentage where 100% indicates that the capacitor 6 is full and 0% indicates that the capacitor is empty. The duration of a particular vaping session may be determined by the amount of electrolyte. The controller 48 may also be adapted to control the display screen 52C to display the remaining duration of the vaping session (in minutes or seconds, for example) or the remaining number of puffs, which may both be estimated or determined from the amount of electrolyte. The remaining duration of the vaping session may depend on the vaping pattern of the user—i.e., if the user takes strong puffs with short gaps between puffs, the electrolyte will be depleted more quickly and the duration of the vaping session may be estimated based on the amount of electrolyte and then displayed to the user on the display screen 52C.

Although exemplary embodiments have been described in the preceding paragraphs, it should be understood that various modifications may be made to those embodiments without departing from the scope of the appended claims. Thus, the breadth and scope of the claims should not be limited to the above-described exemplary embodiments. For example, although the exemplary embodiments all relate to an aerosol generating article that comprises a capacitor, and where the humectant that is inhaled by the user also functions an electrolyte, it will be readily understand that the aerosol generating article may comprise any suitable aerosolisable humectant. In the exemplary embodiments described above, the capacitor may be replaced with an aerosol generating material that comprises a suitable aerosol-former and the visual indicator may be controlled to notify the user of the amount of aerosol-former remaining in the aerosol generating article.

The amount of humectant may be estimated or determined by the controller of the aerosol generating device using any suitable method. For example, the amount of humectant remaining in the aerosol generating article may be estimated or determined based on one or more electrical parameters that are known to vary with the amount of humectant such as resistance or capacitance, e.g., by using a pair of electrode to measure one or more of resistive, capacitive or electrical load. Other suitable methods for estimating or determining the amount of humectant (e.g., aerosol-former) may also be used as would be known to the person skilled in the art.

Any combination of the above-described features in all possible variations thereof is encompassed by the present disclosure unless otherwise indicated herein or otherwise clearly contradicted by context.

Unless the context clearly requires otherwise, throughout the description and the claims, the words “comprise”, “comprising”, and the like, are to be construed in an inclusive as opposed to an exclusive or exhaustive sense: that is to say, in the sense of “including, but not limited to”.

1. An aerosol generating system comprising:
an aerosol generating article comprising a capacitor, the capacitor comprising an electrolyte which, when heated, generates an aerosol for inhalation by a user; and
an aerosol generating device configured to receive, in use, the aerosol generating article, the aerosol generating device comprising:
a visual indicator; and
a controller configured to:
estimate or determine the amount of electrolyte in the capacitor; and
control the visual indicator based on the amount of electrolyte.

2. The aerosol generating system according to claim 1, wherein the visual indicator comprises one or more light emitters, and wherein the controller is configured to change one or both of a colour and an intensity of light emitted by each light emitter based on the amount of electrolyte estimated or determined by the controller.

3. The aerosol generating system according to claim 1, wherein the visual indicator comprises one or more light emitters, and wherein the controller is adapted to control each light emitter to blink.

4. The aerosol generating system according to claim 3, wherein the controller is configured to change a frequency at which each light emitter blinks based on the amount of electrolyte estimated or determined by the controller.

5. The aerosol generating system according to claim 3, wherein the controller is configured to control each light emitter to blink if the amount of electrolyte estimated or determined by the controller is below a predefined threshold.

6. The aerosol generating system according to claim 5, wherein the predetermined threshold is indicative of a maximum amount of electrolyte.

7. The aerosol generating system according to claim 5, wherein the predetermined threshold is indicative of a minimum amount of electrolyte.

8. The aerosol generating system according to claim 1, wherein the visual indicator comprises one or more light emitters and a plurality of sections or panels, and wherein the controller is configured to control each light emitter to light up a predefined number of the plurality of sections or panels based on the amount of electrolyte estimated or determined by the controller.

9. The aerosol generating system according to claim 1, wherein the visual indicator is formed in a shape of a ring.

10. The aerosol generating system according to claim 1, wherein the aerosol generating device includes an opening for receiving the aerosol generating article, and wherein the visual indicator substantially surrounds the opening.

11. The aerosol generating system according to claim 1, wherein the visual indicator is a display screen.

12. A method of visually indicating to a user the amount of electrolyte in a capacitor of an aerosol generating article, wherein the electrolyte, when heated, generates an aerosol for inhalation by a user, the method comprising controlling a visual indicator of an aerosol generating device configured to receive, in use, the aerosol generating article, based on the amount of electrolyte.

13. The method according to claim 12, wherein the visual indicator comprises one or more light emitters, and wherein the method comprises one or both of:
changing one or both of a colour and an intensity of the light emitted by each light emitter based on the amount of electrolyte, and
changing a frequency at which each light emitter blinks based on the amount of electrolyte.

14. The method according to claim 12, wherein the visual indicator comprises a plurality of sections or panels, and wherein the method comprises lighting up a predefined number of the plurality of sections or panels based on the amount of electrolyte.

15. The method according to claim 12, wherein the visual indicator is a display screen, and wherein the method comprises displaying information on the display screen that is directly or indirectly indicative of the amount of electrolyte.
